(19) United States
(12) Patent Application Publication
(10) Pub. No.: US 2011/0148546 A1
(43) Pub. Date: Jun. 23, 2011

(54) Multilayer Component

(76) Inventors: Thomas Feichtinger, Graz (AT); Sebastian Brunner, Graz (AT)

(21) Appl. No.: 13/010,567

(22) Filed: Jan. 20, 2011

Related U.S. Application Data
(63) Continuation of application No. PCT/EP2009/059577, filed on Jul. 24, 2009.

(30) Foreign Application Priority Data
Jul. 28, 2008 (DE) 10 2008 035 102.4

(51) Int. Cl. H03H 7/01

(52) U.S. Cl. 333/185

(57) ABSTRACT

A multilayer component includes at least one inductive region and at least one capacitive region. The inductive region includes a ferrite ceramic. Electrode structures are arranged on the outwardly facing top side of the inductive region. The electrode structures form at least one coil structure having an inductance.

This application is a continuation of co-pending International Application No. PCT/EP2009/059577, filed Jul. 24, 2009, which designated the United States and was not published in English, and which claims priority to German Application No. 10 2008 035 102.4, filed Jul. 28, 2008, both of which applications are incorporated herein by reference.

### BACKGROUND

A multilayer component comprising a varistor and an LC filter is known from the German publication 10 2005 025 680 A1.

### SUMMARY

In one aspect, a multilayer component is specified that allows a broad spectrum of possible LC filter designs.

A multilayer component comprises at least one inductive region and at least one capacitive region. The inductive region comprises a ferrite ceramic. Electrode structures are arranged on the outwardly facing top side of the inductive region. The electrode structures form at least one coil structure comprising an inductance.

The coil structure preferably lies in one plane. In one embodiment, the coil structure is applied on the ferrite ceramic. The coil structure has a spiral form, running from the inner portion outward. The coil structure has spirally running tracks. The tracks preferably have a width greater than their height in cross section.

The coil structure, which is arranged in an outwardly facing top side of the inductive region of the multilayer component, comprises one or more of the following metals: copper, silver, palladium and/or platinum. The coil structure can also comprise further suitable metals.

In one embodiment, the coil structure has the form of a spiral. However, the coil structure can also have any suitable structure that is suitable for performing the function of the coil.

The coil structure on the inductive region of the multilayer component is preferably constructed in a photolithographic method, such as a photo laser imaging method, for example, on the outwardly facing top side of the inductive region.

The coil structure is preferably covered by means of a passivation layer. The passivation layer can comprise, for example, a polymer or a glass. The passivation layer can be applied, for example, by means of a screen printing method or by means of spraying on the top side of the component.

Furthermore, the inductive region can have further electrode structures arranged in the interior of the inductive region.

The capacitive region of the multilayer component has a plurality of internal electrodes. The internal electrodes of the capacitive region comprise at least one capacitance and at least one nonlinear resistance.

The electrode structures of the inductive region and also the internal electrodes of the capacitive region and also, if appropriate, further internal electrodes of the inductive region comprise conductor tracks and plated-through holes.

Plated-through holes should be understood to be electrically conductive connections between two or more conductor tracks on different planes. By means of a plated-through hole, by way of example, a conductor track on a first plane can be electrically conductively connected to a further conductor track on a second plane arranged thereabove or therebelow.

In one preferred embodiment, the plated-through holes have a conical form. Conical plated-through holes can be produced, for example, by means of conical needles or by means of a laser in the green sheets of a multilayer component. Multilayer components are often produced by means of so-called green sheets stacked one above another. Conductor tracks are printed on the green sheets by means of screen printing, for example. The stack of printed green sheets is subsequently sintered at high temperatures in a furnace.

Conical plated-through holes make it possible, for example, for wide conductor tracks on a first side of a layer of the multilayer component to be contact-connected to relatively narrow conductor tracks lying close to one another on a second side of the layer. As a result, a greater configurational freedom is possible in the design of the conductor tracks.

In a further embodiment, by way of example, the conical plated-through holes of two layers lying one above the other can be directed with the vertices toward one another. As a result, by way of example, it is possible to effect a contact-connection from a wide conductor track via a relatively narrow conductor track through to once again a wide conductor track.

In one embodiment, the capacitive region comprises a varistor ceramic.

In a further embodiment, the capacitive region comprises a capacitor ceramic.

In one embodiment, the ferrite ceramic of the inductive region can comprise nickel-zinc ferrites (NiZn), nickel-copper-zinc ferrites (NiCuZn), or nickel-zinc-cobalt ferrites (NiZnCo).

In a further embodiment, the ferrite ceramic of the inductive region can comprise hexagonal ferrites.

The use of a ferrite ceramic for the construction of the inductance makes it possible to achieve very high inductances because ferrite ceramics have a significantly higher permeability in comparison with conventional multilayer components. The ferrite ceramics of the multilayer component preferably have a permeability that is greater than 1. Preferably, the ferrite ceramic has a permeability of between 1 and 50.

In one embodiment, the varistor ceramic of the capacitive region can comprise a zinc oxide bismuth antimony (ZnO—Bi—Sb) ceramic or a zinc oxide praseodymium (ZnO—Pr) ceramic.

In one embodiment, the capacitor ceramic of the capacitive region can comprise an NPO ceramic.

In one embodiment, at least one inductance of the inductive region and at least one capacitance of the capacitive region of the multilayer component form an LC filter structure. The LC filter structure can have a T-LC filter structure or a Pi-LC filter structure.

In one embodiment, the multilayer component can comprise a metallic layer between the capacitive region and the inductive region. The metallic interlayer preferably serves as a diffusion barrier between a capacitive region and an inductive region of the multilayer component. The metallic interlayer approximately completely prevents the diffusion between the two regions. Without a metal-containing interlayer, for example, dopants from the varistor ceramic could diffuse into the ferrite ceramic or dopants of the ferrite ceramic could diffuse into the varistor ceramic.

The multilayer component comprises a plurality of external contacts for making contact with the electrode structure and the internal electrodes of the multilayer component. In one preferred embodiment, the external contacts are embodied in array form. This can involve a land grid array (LGA) or a ball grid array (BGA).

In one embodiment, the varistor ceramic has an ESD (electrostatic discharge) protection function.

In one embodiment, the capacitive region of the multilayer component has a multilayer ceramic capacitor.

The multilayer component described above makes it possible to integrate an ESD protection function and a filter function in an individual device.

It is also possible to arrange a plurality of LC filters in one component as an array. For this purpose, a plurality of LC filters are arranged alongside one another, for example, in a common component.

The subject matter described above will be explained in greater detail on the basis of the following figures and exemplary embodiments.

### BRIEF DESCRIPTION OF THE DRAWINGS

The drawings described below should not be regarded as true to scale. Rather, for the sake of better illustration, individual dimensions may be illustrated as enlarged, reduced in size and even distorted. Elements which are identical to one another or which perform the same functions are designated by the same reference symbols.

FIG. 1 shows a schematic construction of a first exemplary embodiment of a multilayer component;

FIG. 2 shows a three-dimensional view of a further exemplary embodiment of the multilayer component;

FIG. 3 shows an equivalent circuit diagram of an LC filter; and

FIG. 4 shows an equivalent circuit diagram of a Pi-type LC filter.

The following list of reference symbols may be used in conjunction with the drawings:
1 inductive region
2 capacitive region
3 electrode structure
4 coil structure
5 inductance
6 internal electrode
7 capacitance
9 external contact
10 plated-through hole
11 passivation layer
12 varistor
13 LC filter

### DETAILED DESCRIPTION OF ILLUSTRATIVE EMBODIMENTS

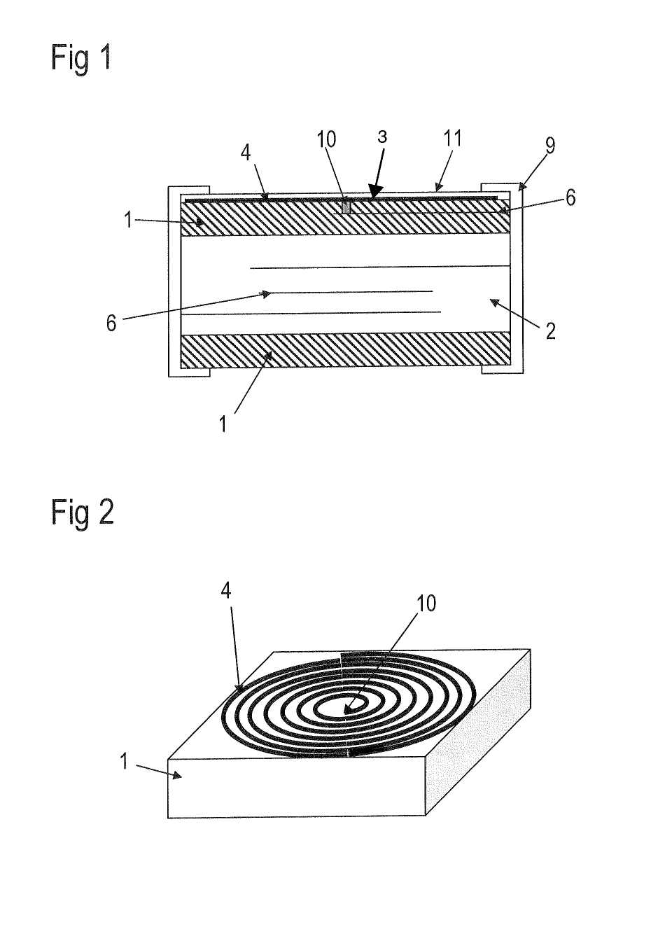

FIG. 1 illustrates a schematic view of a first embodiment of a multilayer component. The multilayer component has two inductive regions 1, between which a capacitive region 2 is arranged. The inductive regions 1 preferably comprise a ferrite ceramic. The capacitive region 2 can comprise a varistor ceramic or a capacitor ceramic. The inductive region 1 and the capacitive region 2 each have electrodes. The electrodes can be present either within the regions as internal electrodes 6 or as electrode structures 3 on the top side of the inductive region 1. The internal electrodes 6 of the capacitive region 2 form at least one capacitance and a nonlinear resistance. The inductive region 1 has, on the outwardly facing top side, an electrode structure 3 forming at least one coil structure 4 and at least one inductance. The inductive region 1 has further internal electrodes 6 and plated-through holes 10, serving, for example, as feeds for the coil structure 4 and/or the inductance on the top side of the inductive region 1. The inductance of the inductive region 1 and the capacitance of the capacitive region 2 form an LC filter.

On the top side of the multilayer component, the coil structure 4 is covered by a passivation layer 11. The passivation layer 11 preferably protects the coil structure 4 against corrosion or other harmful influences.

A metal interlayer can be arranged between the inductive region 1 and the capacitive region 2. The interlayer is not illustrated in this embodiment. The metallic interlayer serves as a diffusion barrier between the inductive region 1 and the capacitive region 2. For making contact externally, the multilayer component has a plurality of external contacts 9. The external contacts 9 are electrically connected to the electrodes of the inductive region 1 and of the capacitive region 2. The varistor ceramic of the capacitive region 2 preferably has an ESD protection function.

FIG. 2 shows a three-dimensional view of a further embodiment of the multilayer component. This view shows the coil structure 4 on the top side of the inductive region 1 in the form of a circular spiral. However, the coil structure 4 can also have any other suitable form. For making contact with the coil structure 4, the inductive region 1 has a plated-through hole 10 in the center of the coil structure 4. The plated-through hole 10 electrically connects the coil structure 4 to further internal electrodes of the inductive region 1 or else of the capacitive region 2.

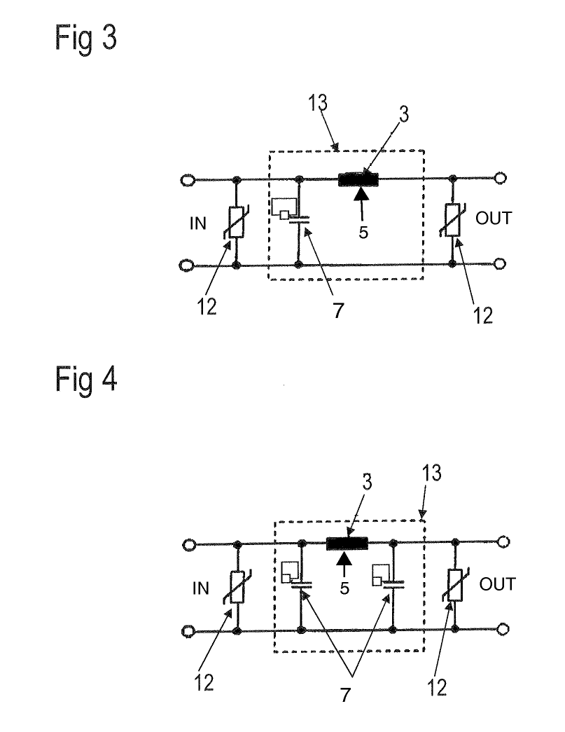

FIG. 3 shows an equivalent circuit diagram of an LC filter 13 of an embodiment of the multilayer component. The LC filter 13 comprises an inductance 5 and a capacitance 7, and is provided with two varistors 12. The capacitance 7 is connected between two parallel main lines, which lead from the input (on the left of FIG. 3) of the LC filter 13 to the output (on the right of FIG. 3). The inductance 5 is connected in series in one of the main lines. The varistors 12 are connected parallel with the capacitance 7 between the main lines. The varistors 12 may serve as ESD protection elements for the LC filter 13.

FIG. 4 shows an equivalent circuit diagram of an LC filter 13 of a further embodiment of the multilayer component. The LC filter 13 of FIG. 4 has the configuration of a pi-type LC filter. It comprises an inductance 5 and two capacitances 7, and is provided with two varistors 12. The capacitances 7 are connected in parallel to one another between two parallel main lines, which lead from the input (on the left of FIG. 4) of the LC filter 13 to the output (on the right of FIG. 4). The inductance 5 is connected in series in one of the main lines and between the capacitances 7. The varistors 12 are connected parallel with the capacitances 7 between the main lines. The varistors 12 may serve as ESD protection elements for the LC filter 13.

Although only a restricted number of possible developments of the invention could be described in the embodiments, the invention is not restricted thereto. It is possible, in principle, for the multilayer component to have a higher number of ceramic regions.

The invention is not restricted to the number of elements illustrated.

The description of the subjects specified here is not restricted to the individual specific embodiments; rather, the features of the individual embodiments can be combined with one another in any desired manner in so far as is technically expedient.

What is claimed is:

1. A multilayer component, comprising:
an inductive region that comprises a ferrite ceramic, wherein an inductive structure is disposed within the inductive region;
a capacitive region adjacent the inductive region, wherein a capacitance structure is disposed within the capacitive region; and
electrode structures arranged on the outwardly facing top side of the inductive region, wherein the electrode structures form at least one coil structure having an inductance.

2. The multilayer component according to claim 1, wherein the coil structure comprises a spiral structure.

3. The multilayer component according to claim 1, wherein the coil structure comprises Cu, Ag, Pd, or Pt.

4. The multilayer component according to claim 1, further comprising a passivation layer covering the coil structure.

5. The multilayer component according to claim 1, wherein the capacitive region comprises internal electrodes that form the capacitance structure and a nonlinear resistance.

6. The multilayer component according to claim 1, wherein the capacitive region comprises a varistor ceramic.

7. The multilayer component according to claim 1, wherein the capacitive region comprises a capacitor ceramic.

8. The multilayer component according to claim 1, wherein the ferrite ceramic comprises NiZn ferrites, NiCuZn ferrites or NiZnCo ferrites.

9. The multilayer component according to claim 1, wherein the ferrite ceramic comprises hexagonal ferrites.

10. The multilayer component according to claim 6, wherein the varistor ceramic comprises a ZnO—Bi—Sb ceramic or a ZnO—Pr ceramic.

11. The multilayer component according to claim 7, wherein the capacitor ceramic comprises an NPO ceramic.

12. The multilayer component according to claim 1, wherein the inductive structure and the capacitance structure form a T-LC filter structure.

13. The multilayer component according to claim 1, wherein the inductive structure and the capacitance structure form a Pi-LC filter structure.

14. The multilayer component according to claim 1, further comprising a metallic layer between the inductive region and the capacitive region.

15. The multilayer component according to claim 14, wherein the metallic layer serves as a diffusion barrier between the inductive region and the capacitive region.

16. The multilayer component according to claim 1, further comprising external contacts arranged in an array.

17. The multilayer component according to claim 1, wherein the array comprises an LGA or BGA.

18. The multilayer component according to claim 6, wherein the varistor ceramic has an ESD protection function.
